(19) United States
(12) Patent Application Publication
(10) Pub. No.: US 2011/0011437 A1
(43) Pub. Date: Jan. 20, 2011

(54) SOLAR CELL AND METHOD FOR MANUFACTURING SOLAR CELL

(75) Inventors: Atsushi DENDA, Chino (JP); Hiromi SAITO, Chino (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/830,715

(22) Filed: Jul. 6, 2010

(30) Foreign Application Priority Data
Jul. 14, 2009 (JP) 2009-165344

(51) Int. Cl. H01L 31/042; H01L 31/18

(52) U.S. Cl. 136/244; 438/80; 257/E31.113; 257/E31.032

(57) ABSTRACT

A solar cell includes a plurality of unit cells connected in series and a first partition portion. Each of the unit cells includes a substrate, a first electrode layer formed on the substrate, a semiconductor layer formed on the first electrode layer, and a second electrode layer formed on the semiconductor layer. The first partition portion has insulation properties and partitions the first electrode layers of the unit cells on the substrate with each the first electrode layers being disposed respectively in a region partitioned by the first partition portion.

### CROSS-REFERENCE TO RELATED APPLICATIONS

This application claims priority to Japanese Patent Application No. 2009-165344 filed on Jul. 14, 2009. The entire disclosure of Japanese Patent Application No. 2009-165344 is hereby incorporated herein by reference.

### BACKGROUND

1. Technical Field

The present invention relates to a solar cell and to a method for manufacturing a solar cell.

2. Related Art

A solar cell converts light energy into electrical energy, and various types of configurations of solar cells have been proposed according to the semiconductor used. In recent years, CIGS-type solar cells have been emphasized for the simple manufacturing process thereof and the ability to realize high conversion efficiency. A CIGS solar cell is configured from a plurality of unit cells connected in a series, where one cell is composed, for example, of a first electrode film formed on a substrate, a thin film that includes a compound semiconductor (copper-indium-gallium-selenide) formed on the first electrode film, and a second electrode film that is formed on the thin film. The first electrode film is divided in each cell by forming a groove in a portion of the first electrode film, and the first electrode film is formed so as to straddle the space between adjacent cells. The thin film and the second electrode film are divided in each cell by forming a groove in the thin film and a portion of the second electrode film so as to extend to the first electrode film. The first electrode film and the second electrode film are electrically connected by providing a groove in a portion of the thin film so as to extend to the first electrode film, and forming the second electrode film within the groove. The second electrode film of each cell is thereby connected to the first electrode film of the adjacent cell, and the unit cells are connected in series (see Japanese Laid-Open Patent Publication No. 2002-319686, for example).

### SUMMARY

The grooves for dividing the solar cell described above into cells are formed by scribing the first electrode film or portions of the second electrode film and thin film using laser light irradiation, a metal needle, or the like. The greatest possible care must be taken during formation of the grooves so as not to cause defects in the quality of other members. A margin for machining error must therefore be added to the scribe region in which the grooves are formed, and the need arises to reserve an even wider area. However, reserving such a wide area increases the size of non-generating regions that do not contribute to the function of the solar cell, and conversion efficiency is reduced.

The present invention was developed in order to overcome at least some of the problems described above, and the present invention can be implemented in the form of the embodiments or applications described below.

A solar cell according to a first aspect includes a plurality of unit cells connected in series and a first partition portion. Each of the unit cells includes a substrate, a first electrode layer formed on the substrate, a semiconductor layer formed on the first electrode layer, and a second electrode layer formed on the semiconductor layer. The first partition portion has insulation properties and partitions the first electrode layers of the unit cells on the substrate with each the first electrode layers being disposed respectively in a region partitioned by the first partition portion.

According to this configuration, the first electrode layer is partitioned by the first partition portion. Specifically, the first electrode layer is partitioned (divided) into cell elements by the first partition portion rather than being partitioned by the conventional scribing process using laser light irradiation, a metal needle, or the like. Consequently, since there is no need for scribe processing of the first electrode layer, no scribing residue is generated, and a highly reliable solar cell can be provided. Since there is also no need to set a scribing width or the like to allow for error in the scribing process, a larger electrical generation region can be formed, and conversion efficiency can be enhanced.

In the solar cell as described above, a top surface of the first partition portion is preferably substantially flash with top surfaces of the first electrode layers.

According to this configuration, the first partition portion and the top surface of the first electrode layer form a uniform surface. Specifically, a flat surface having no level differences is formed. The connection properties between the first partition portion and the semiconductor layer formed on the first electrode layer can thereby be enhanced.

A solar cell according to a second aspect includes a plurality of unit cells connected in series and a second partition portion. Each of the unit cells includes a substrate, a first electrode layer formed on the substrate, a semiconductor layer formed on the first electrode layer, and a second electrode layer formed on the semiconductor layer. The second partition portion has insulation properties and partitions the semiconductor layers and the second electrode layers of the unit cells on the substrate, with each set of the semiconductor layers and the second electrode layers being disposed respectively in a region partitioned by the second partition portion.

According to this configuration, the semiconductor layer and the second electrode layer are partitioned by the second partition portion. Specifically, the semiconductor layer and the second electrode layer are partitioned (divided) into cell elements by the second partition portion rather than being partitioned by the conventional scribing process using laser light irradiation, a metal needle, or the like. Consequently, since there is no need for scribe processing of the second electrode layer, no scribing residue is generated, and a highly reliable solar cell can be provided. Since there is also no need to set a scribing width or the like to allow for error in the scribing process, non-generating regions that do not contribute to electrical generation can be eliminated, the electrical generation region that contributes to electrical generation can be increased in size, and conversion efficiency can be enhanced.

In the solar cell as described above, the semiconductor layers preferably form a groove portion communicating the first electrode layer with the second electrode layer in a region adjacent to the second partition portion with the second electrode layer being formed in the groove portion.

According to this configuration, the groove portion is formed in the region adjacent to the second partition portion. Specifically, the groove portion is formed in the outermost peripheral portion of the unit cell. The second electrode layer is formed in the groove portion, and the first electrode layer and second electrode layer are electrically connected. Consequently, since the second electrode layer formed in the groove portion is formed in the outermost peripheral portion of the unit cell, the region in which the first electrode layer, the semiconductor layer, and the second electrode layer overlap, i.e., the electrical generation region, can be increased in size, and conversion efficiency can be increased.

The solar cell as described above preferably further includes a conductive layer disposed in a region adjacent to the second partition portion with the conductive layer electrically connecting the first electrode layer and the second electrode layer.

According to this configuration, a conductive layer is formed in a region adjacent to the second partition portion. Specifically, the conductive layer is formed in the outermost peripheral portion of the unit cell. Consequently, by forming the conductive layer in the outermost peripheral portion of the unit cell, the region in which the first electrode layer, the semiconductor layer, and the second electrode layer overlap, i.e., the electrical generation region, can be increased in size, and conversion efficiency can be increased.

In the solar cell as described above, the conductive layer is preferably formed using a material having lower electrical resistivity than the first electrode layer and the second electrode layer.

According to this configuration, electrical resistance between the first electrode layer and the second electrode layer can be reduced, and conversion efficiency can be enhanced.

A method for manufacturing a solar cell having a plurality of unit cells connected in series, each of the unit cells including a substrate, a first electrode layer, a semiconductor layer, and a second electrode layer, includes: forming a first partition portion on the substrate to partition a plurality of regions respectively corresponding to the first electrode layers of the unit cells; forming the first electrode layer of each of the unit cells in a corresponding one of the regions partitioned by the first partition portion; forming a second partition portion on the first electrode layer to partition a plurality of regions respectively corresponding to the semiconductor layers and the second electrode layers of the unit cells; forming the semiconductor layer of each of the unit cells in a corresponding one of the regions partitioned by the second partition portion; removing a portion of the semiconductor layer of each of the unit cells in the thickness direction to form a groove portion extending to the first electrode layer; and forming the second electrode layer of each of the unit cells on the semiconductor layer and in the groove portion in a corresponding one of the regions partitioned by the second partition portion.

According to this configuration, the first electrode layer is partitioned for each cell by the first partition portion. The semiconductor layer and the second electrode layer are also partitioned for each cell by the second partition portion. Consequently, since there is no need for scribe processing of the first electrode layer, no scribing residue is generated, and a highly reliable solar cell can be provided. Since there is also no need to set a scribing width or the like to allow for error in the scribing process, non-generating regions that do not contribute to electrical generation can be eliminated, the electrical generation region that contributes to electrical generation can be increased in size, and conversion efficiency can be enhanced.

In the method for manufacturing a solar cell as described above, the removing of the portion of the semiconductor layer preferably includes removing the portion of the semiconductor layer in a region adjacent to the second partition portion to form the groove portion in the region adjacent to the second partition portion.

According to this configuration, the groove portion is formed in a region adjacent to the second partition portion. Specifically, the groove portion is formed in the outermost peripheral portion of the unit cell. The second electrode layer is then formed in the groove portion, and the first electrode layer and second electrode layer are electrically connected. Consequently, since the second electrode layer formed in the groove portion is formed in the outermost peripheral portion of the unit cell, the region in which the first electrode layer, the semiconductor layer, and the second electrode layer overlap, i.e., the electrical generation region, can be increased in size, and conversion efficiency can be increased.

A method for manufacturing a solar cell having a plurality of unit cells connected in series, each of the unit cells including a substrate, a first electrode layer, a semiconductor layer, and a second electrode layer, includes: forming a first partition portion on the substrate to partition a plurality of regions respectively corresponding to the first electrode layers of the unit cells; forming the first electrode layer of each of the unit cells on the substrate in a corresponding one of the regions partitioned by the first partition portion; forming a second partition portion on the first electrode layer to partition a plurality of regions respectively corresponding to the semiconductor layers and the second electrode layers of the unit cells; forming a conductive layer on the first electrode layer of each of the unit cells in a corresponding one of the regions partitioned by the second partition portion with the conductive layer electrically connecting the first electrode layer and the second electrode layer; forming the semiconductor layer of each of the unit cells on the first electrode layer in a corresponding one of the regions partitioned by the second partition portion; and forming the second electrode layer of each of the unit cells on the semiconductor layer in a corresponding one of the regions partitioned by the second partition portion.

According to this configuration, the first electrode layer is partitioned for each cell by the first partition portion. The semiconductor layer and the second electrode layer are also partitioned for each cell by the second partition portion. Furthermore, by forming the conductive layer in advance on the first electrode layer, the first electrode layer and the second electrode layer are electrically connected. Consequently, since there is no need for scribe processing of the first electrode layer, no scribing residue is generated, and a highly reliable solar cell can be provided. Since there is also no need to set a scribing width or the like to allow for error in the scribing process, non-generating regions that do not contribute to electrical generation can be eliminated, the electrical generation region that contributes to electrical generation can be increased in size, and conversion efficiency can be enhanced.

In the method for manufacturing a solar cell as described above, the forming of the conductive layer preferably includes forming the conductive layer in a region adjacent to the second partition portion.

According to this configuration, the conductive layer is formed adjacent to the second partition portion. Specifically, the conductive layer is formed in the outermost peripheral portion of the unit cell. Consequently, since the conductive layer is formed in the outermost periphery of the unit cell, the region in which the first electrode layer, the semiconductor layer, and the second electrode layer overlap, i.e., the electrical generation region, can be increased in size, and conversion efficiency can be increased.

### BRIEF DESCRIPTION OF THE DRAWINGS

Referring now to the attached drawings which form a part of this original disclosure:

FIG. 1 is a view showing the structure of the solar cell according to a first embodiment;

FIG. 2 is a process view showing the method for manufacturing a solar cell according to the first embodiment;

FIG. 3 is a process view showing the method for manufacturing a solar cell according to the first embodiment;

FIG. 4 is a view showing the structure of the solar cell according to a second embodiment.

FIG. 5 is a process view showing the method for manufacturing a solar cell according to the second embodiment;

FIG. 6 is a process view showing the method for manufacturing a solar cell according to the second embodiment;

### DETAILED DESCRIPTION OF EXEMPLARY EMBODIMENTS

### First Embodiment

A first embodiment of the present invention will be described hereinafter with reference to the drawings. Each of the members shown in the drawings is shown sufficiently large to recognize, and members are not shown to scale in relation to each other.

### Structure of Solar Cell

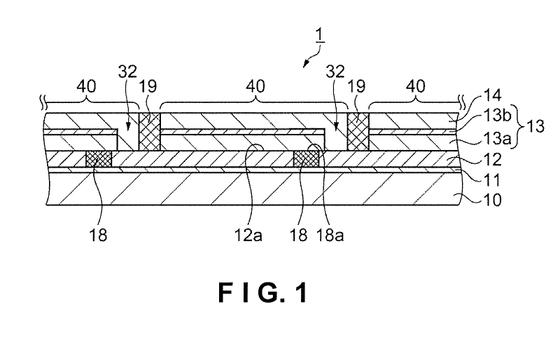

The structure of the solar cell will first be described. In the present embodiment, the structure of a CIGS-type solar cell will be described. FIG. 1 is a sectional view showing the structure of the solar cell according to the present embodiment.

As shown in FIG. 1, the solar cell 1 is composed of an aggregate of cells 40 that are composed of a substrate 10; a base layer 11 formed on the substrate 10; a first electrode layer 12 formed on the base layer 11; a semiconductor layer 13 formed on the first electrode layer 12; and an second electrode layer 14 formed on the semiconductor layer 13.

Adjacent unit cells 40 are separated by first partition portions 18 and second partition portions 19. Specifically, the first electrode layer 12 is divided for each unit cell 40 by the first partition portions 18, and the first electrode layer 12 is a region partitioned by the first partition portions 18 and formed so as to bridge the spaces between adjacent unit cells 40. The semiconductor layer 13 and the second electrode layer 14 are divided for each unit cell 40 by the second partition portions 19. The second electrode layer 14 is formed within groove portions 32 formed in portions of the semiconductor layer 13, and the second electrode layer 14 of the unit cells 40 is connected to the first electrode layer 12 of the other adjacent unit cells 40, whereby the unit cells 40 are each connected in series. The desired voltage in the solar cell 1 can thus be designed and changed to any value by appropriately setting the number of cells 40 that are connected in series.

The substrate 10 is a substrate in which at least the surface thereof on the side of the first electrode layer 12 has insulating properties. Specific examples of substrates that can be used include glass (blue sheet glass or the like) substrates, stainless steel substrates, polyimide substrates, and carbon substrates.

The base layer 11 is a layer having insulating properties that is formed on the substrate 10, and an insulation layer primarily composed of SiO₂ (silicon dioxide), or an iron fluoride layer may be provided. The base layer 11 has insulation properties, and has the function of maintaining adhesion between the substrate 10 and the first electrode layer 12 formed on the substrate 10. The base layer 11 may be omitted when the substrate 10 has the characteristics described above.

The first partition portions 18 are formed on the base layer 11. The first partition portions 18 have insulation properties, and partition (divide) the first electrode layer 12 for each unit cell 40.

The first electrode layer 12 is formed on the base layer 11, in the region partitioned by the first partition portions 18. The first electrode layer 12 is electrically conductive, and may be formed using molybdenum (Mo), for example. The top surface 12a of the first electrode layer 12 and the top surfaces 18a of the first partition portions 18 are formed so as to have the same height. Specifically, a uniform, flat surface is formed by the top surface 12a of the first electrode layer 12 and the top surfaces 18a of the first partition portions 18.

The semiconductor layer 13 is composed of a first semiconductor layer 13a and a second semiconductor layer 13b. The first semiconductor layer 13a is formed on the first electrode layer 12, and is a p-type semiconductor layer that includes copper (Cu), indium (In), gallium (Ga, and selenium (Se) (CIGS semiconductor layer).

The second semiconductor layer 13b is formed on the first semiconductor layer 13a, and is a cadmium sulfide (CdS), zinc oxide (ZnO), indium sulfide (InS), or other n-type semiconductor layer.

The second electrode layer 14 is a transparent electrode layer formed on the second semiconductor layer 13b, and is composed of ZnOAl or another transparent electrode (TCO: transparent conducting oxides), AZO, or the like. The groove portions 32 extending to the first electrode layer 12 in the thickness direction of the semiconductor layer 13 are formed in portions of the semiconductor layer 13, and the second electrode layer 14 is formed within the groove portions 32 as well. The first electrode layer 12 and the second electrode layer 14 are thereby electrically connected.

The second partition portions 19 are formed on the first electrode layer 12. The second partition portions 19 partition (divide) the semiconductor layer 13 and the second electrode layer 14 for each unit cell 40, and have insulation properties.

The groove portions 32 are provided in regions adjacent to the second partition portions 19. Consequently, the second electrode layer 14 formed within the groove portions 32 is formed adjacent to the second partition portions 19. In other words, the second electrode layer 14 is formed in the outermost peripheral portions of the unit cells 40. Since the unit cells 40 are divided from each other by the second partition portions 19, which have insulation properties, insulation properties are maintained between adjacent unit cells 40. By thus providing the second electrode layer 14 in the groove portions 32 in the outermost peripheral portions of the unit cells 40, the region in which the first electrode layer 12, the semiconductor layer 13, and the second electrode layer 14 overlap, i.e., the electrical generation region, can be increased in size.

When sunlight or other light is incident on the CIGS-type solar cell 1 configured as described above, electrons (−) and positive holes (+) occur in pairs in the semiconductor layer 13, and the electrons (−) collect in the n-type semiconductor layer, and the positive holes (+) collect in the p-type semiconductor layer at the joint surface between the p-type semiconductor layer (first semiconductor layer 13a) and the n-type semiconductor layer (second semiconductor layer 13b). As a result, an electromotive force occurs between the n-type semiconductor layer and the p-type semiconductor layer. In this state, a current can be directed to the outside by connecting an external conductor to the first electrode layer 12 and the second electrode layer 14.

### Method for Manufacturing Solar Cell

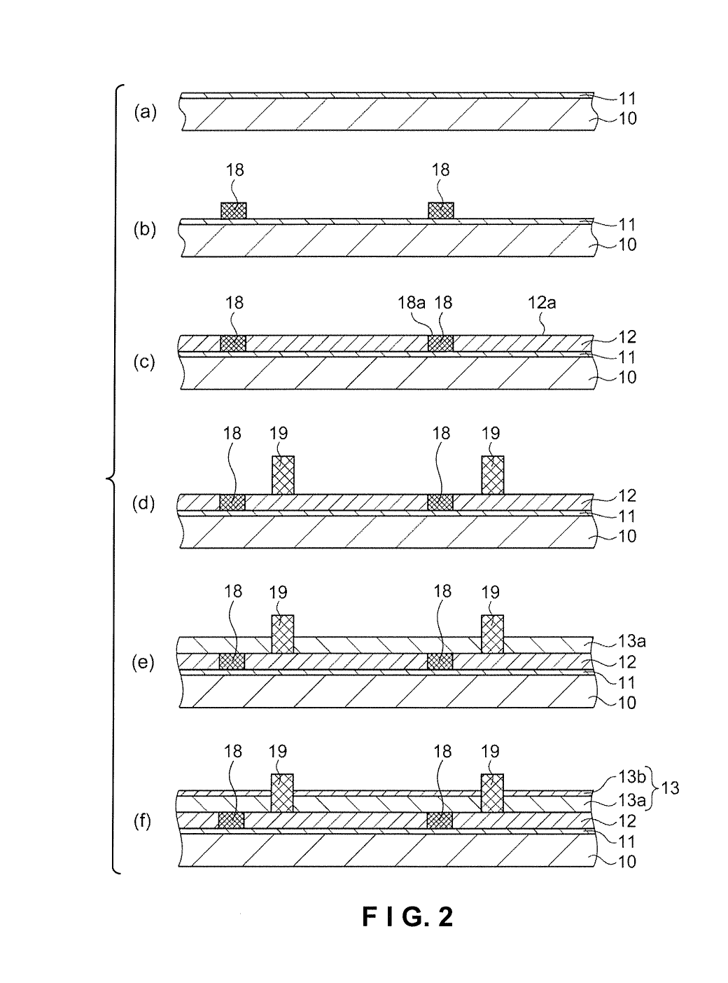

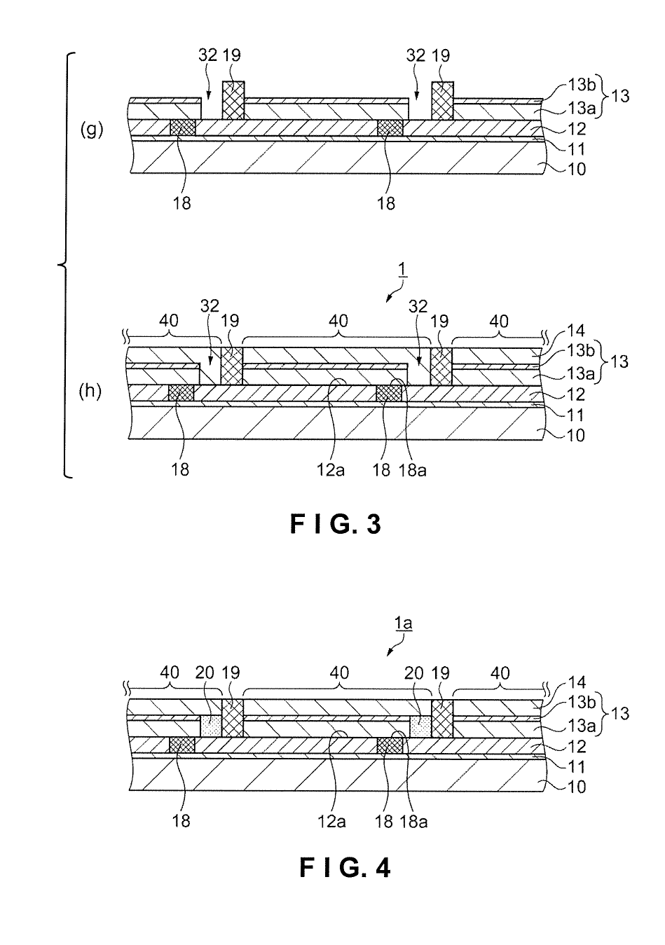

The method for manufacturing the solar cell will next be described. In the present embodiment, a method for manufacturing a CIGS-type solar cell will be described. FIGS. 2 and 3 are process views showing the method for manufacturing a solar cell according to the present embodiment.

In a base layer formation step shown in FIG. 2(a), an insulation layer primarily composed of SiO₂ (silicon dioxide) or an iron fluoride base layer 11 is formed on one surface of a substrate 10 composed of blue sheet glass, stainless steel, or other material. The base layer 11 can be formed by heat treatment or another method. The base layer formation step may be omitted when the substrate 10 as such has the effects of the base layer described above.

In a first partition portion formation step shown in FIG. 2(b), the first partition portions 18 having insulation properties are formed on the base layer 11 to partition the region in which the first electrode layer 12 is formed. The first partition portions 18 are formed, for example, by applying a liquid material that includes an insulating material for forming the first partition portions 18 on the base layer 11 by a printing method, an inkjet method, or another method, and baking the applied solution. The first partition portions 18 are formed in the first partition portion formation step so as to have the same thickness as the first electrode layer 12 formed in the subsequent step.

In a first electrode layer formation step shown in FIG. 2(c), the first electrode layer 12 is formed in the region partitioned by the first partition portions 18. The first electrode layer 12 is formed, for example, by using a printing method, an inkjet method, or another method to apply a liquid material that includes molybdenum (Mo) for forming the first electrode layer 12 in the region partitioned by the first partition portions 18, and baking the applied molybdenum. The first electrode layer 12 is formed so that the top surface 12a of the first electrode layer 12 and the top surfaces 18a of the first partition portions 18 have the same height. Specifically, a uniform, flat surface is formed by the top surface 12a of the first electrode layer 12 and the top surfaces 18a of the first partition portions 18.

In a second partition portion formation step shown in FIG. 2(d), the second partition portions 19 having insulation properties are formed to partition the region on the first electrode layer 12 in which the semiconductor layer 13 and the second electrode layer 14 are formed. The second partition portions 19 are formed, for example, by applying a liquid material that includes an insulating material for forming the second partition portions 19 on the first electrode layer 12 by a printing method, an inkjet method, or another method, and baking the applied insulating material.

In a first semiconductor layer formation step shown in FIG. 2(e), the first semiconductor layer 13a is formed in the region partitioned by the second partition portions 19. The first semiconductor layer 13a is formed, for example, by using a printing method, an inkjet method, or another method to apply a liquid material that includes a compound semiconductor material composed of copper (Cu), indium (In), gallium (Ga), and selenium (Se) for forming the first semiconductor layer 13a in the region partitioned by the second partition portions 19, and baking the applied compound semiconductor material. A p-type semiconductor layer (CIGS layer) is thereby formed.

In a second semiconductor layer formation step shown in FIG. 2(f), the second semiconductor layer 13b is formed on the first semiconductor layer 13a in the region partitioned by the second partition portions 19. The second semiconductor layer 13b is formed, for example, by using a printing method, an inkjet method, or another method to apply a liquid material that includes a CdS, ZnO, or InS material as the second semiconductor layer 13b in the region partitioned by the second partition portions 19, and baking the applied material. An n-type semiconductor layer is thereby formed. The semiconductor layer 13 is composed of a first semiconductor layer 13a and a second semiconductor layer 13b.

In a groove portion formation step shown in FIG. 3(g), portions of the semiconductor layer 13 are removed in the thickness direction, and groove portions 32 are formed in the regions adjacent to the second partition portions 19, in the region partitioned by the second partition portions 19. Specifically, the portions of the semiconductor layer 13 are removed using laser light irradiation, a metal needle, or another method.

In a second electrode layer formation step shown in FIG. 3(h), the second electrode layer 14 is formed on the semiconductor layer 13 and within the groove portions 32, in the region partitioned by the second partition portions 19. The second electrode layer 14 is formed, for example, by using a printing method, an inkjet method, or another method to apply a liquid material that includes ZnOAl or another transparent electrode (TCO) material for forming the second electrode layer 14 in the region partitioned by the second partition portions 19, and baking the applied material. By forming the second electrode layer 14, the first electrode layer 12 and the second electrode layer 14 are electrically connected.

By the process described above, a CIGS-type solar cell 1 can be manufactured in which a plurality of unit cells 40 is connected in series.

The effects described below are obtained through the first embodiment described above.

(1) The first partition portions 18 are formed, and the first electrode layer 12 is divided for each unit cell 40. The second partition portions 19 are formed, and the semiconductor layer 13 and the second electrode layer 14 are divided. Consequently, there is no need to divide (scribe) each of the unit cells 40 using laser light irradiation, a metal needle, or the like in the present embodiment. There is therefore no residue generated by a scribing process or the like, and a highly reliable solar cell can be provided. Since there is also no need to set a scribing width or the like to allow for error in the scribing process, a larger electrical generation region can be formed, and conversion efficiency can be enhanced.

(2) The groove portions 32 are formed in the regions adjacent to the second partition portions 19, and the second electrode layer 14 is formed within the groove portions 32. Specifically, the second electrode layer 14 is formed in the outermost peripheral portion of each unit cell 40. The region in which first electrode layer 12, the semiconductor layer 13, and the second electrode layer 14 overlap can thereby be increased in size, and conversion efficiency can be further increased.

(3) The first electrode layer 12 and the first partition portions 18 are formed so that the thickness of the first electrode layer 12 and the first partition portions 18 is the same. A uniform flat surface devoid of level differences is thereby formed by the top surface 12a of the first electrode layer 12 of the top surfaces 18a of the first partition portions 18. The connection properties with the semiconductor layer 13 formed on the first electrode layer 12 and the first partition portions 18 can thereby be enhanced.

### Second Embodiment

A second embodiment will next be described with reference to the drawings. Each of the members shown in the drawings is shown sufficiently large to recognize, and members are not shown to scale in relation to each other.

### Structure of Solar Cell

The structure of the solar cell will first be described. In the present embodiment, the structure of a CIGS-type solar cell will be described. FIG. 4 is a sectional view showing the structure of the solar cell according to the present embodiment.

As shown in FIG. 4, the solar cell 1a is composed of an aggregate of cells 40 that are composed of a substrate 10; a base layer 11 formed on the substrate 10; a first electrode layer 12 formed on the base layer 11; a semiconductor layer 13 formed on the first electrode layer 12; a second electrode layer 14 formed on the semiconductor layer 13; and conductive layers 20 for electrically connecting the first electrode layer 12 and the second electrode layer 14.

Adjacent unit cells 40 are separated by the first partition portions 18 and the second partition portions 19. Specifically, the first electrode layer 12 is divided for each unit cell 40 by the first partition portions 18, and the first electrode layer 12 is formed so as to straddle the space between adjacent unit cells 40. The semiconductor layer 13 and the second electrode layer 14 are divided for each unit cell 40 by the second partition portions 19. The second electrode layer 14 of the unit cells 40 is connected to the first electrode layer 12 of the other adjacent unit cells 40 via the conductive layers 20, whereby the unit cells 40 are each connected in series. The desired voltage in the solar cell 1a can thus be designed and changed to any value by appropriately setting the number of cells 40 that are connected in series.

The substrate 10 is a substrate in which at least the surface thereof on the side of the first electrode layer 12 has insulating properties. Specific examples of substrates that can be used include glass (blue sheet glass or the like) substrates, stainless steel substrates, polyimide substrates, and carbon substrates.

The base layer 11 is a layer having insulating properties that is formed on the substrate 10, and an insulation layer primarily composed of SiO₂ (silicon dioxide), or an iron fluoride layer may be provided. The base layer 11 has insulation properties, and has the function of maintaining adhesion between the substrate 10 and the first electrode layer 12 formed on the substrate 10. The base layer 11 may be omitted when the substrate 10 has the characteristics described above.

The first partition portions 18 are formed on the base layer 11. The first partition portions 18 have insulation properties, and partition (divide) the first electrode layer 12 for each unit cell 40.

The first electrode layer 12 is formed on the base layer 11, in the region partitioned by the first partition portions 18. The first electrode layer 12 is electrically conductive, and may be formed using molybdenum (Mo), for example. The top surface 12a of the first electrode layer 12 and the top surfaces 18a of the first partition portions 18 are formed so as to have the same height. Specifically, a uniform, flat surface is formed by the top surface 12a of the first electrode layer 12 and the top surfaces 18a of the first partition portions 18.

The semiconductor layer 13 is composed of a first semiconductor layer 13a and a second semiconductor layer 13b. The first semiconductor layer 13a is formed on the first electrode layer 12, and is a p-type semiconductor layer that includes copper (Cu), indium (In), gallium (Ga, and selenium (Se) (CIGS semiconductor layer).

The second semiconductor layer 13b is formed on the first semiconductor layer 13a, and is a cadmium sulfide (CdS), zinc oxide (ZnO), indium sulfide (InS), or other n-type semiconductor layer.

The second electrode layer 14 is a transparent electrode layer formed on the second semiconductor layer 13b, and is composed of ZnOAl or another transparent electrode (TCO: transparent conducting oxides), AZO, or the like.

The conductive layers 20 are electrically conductive, and electrically connect the first electrode layer 12 and the second electrode layer 14. The conductive layers 20 are formed by a material having lower electrical resistivity than the first electrode layer 12 and the second electrode layer 14. Specifically, copper (Cu) or a material composed primarily of copper, or gold (Au), silver (Ag), nickel (Ni), a copper-manganese compound, or another material may be used to form the conductive layers 20. By thus using a material having low electrical resistivity, the electrical resistance between the first electrode layer 12 and the second electrode layer 14 can be reduced.

The second partition portions 19 are formed on the first electrode layer 12. The second partition portions 19 partition (divide) the semiconductor layer 13 and the second electrode layer 14 for each unit cell 40, and have insulation properties.

The conductive layers 20 are provided in the regions adjacent to the second partition portions 19. In other words, the conductive layers 20 are formed in the outermost peripheral portions of the unit cells 40. Since the unit cells 40 are separated by the second partition portions 19 having insulation properties, insulation properties are maintained between adjacent unit cells 40. By thus providing the conductive layers 20 in the outermost peripheral portions of the unit cells 40, the region in which the first electrode layer 12, the semiconductor layer 13, and the second electrode layer 14 overlap, i.e., the electrical generation region, can be increased in size.

When sunlight or other light is incident on the CIGS-type solar cell 1a configured as described above, electrons (−) and positive holes (+) occur in pairs in the semiconductor layer 13, and the electrons (−) collect in the n-type semiconductor layer, and the positive holes (+) collect in the p-type semiconductor layer at the joint surface between the p-type semiconductor layer (first semiconductor layer 13a) and the n-type semiconductor layer (second semiconductor layer 13b). As a result, an electromotive force occurs between the n-type semiconductor layer and the p-type semiconductor layer. In this state, a current can be directed to the outside by connecting an external conductor to the first electrode layer 12 and the second electrode layer 14.

### Method for Manufacturing Solar Cell

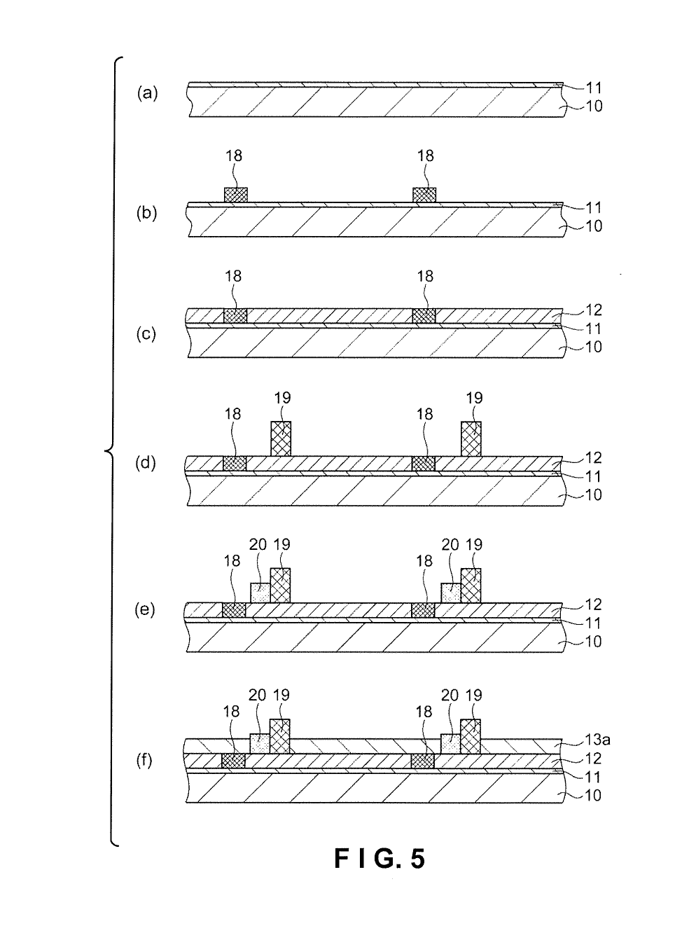

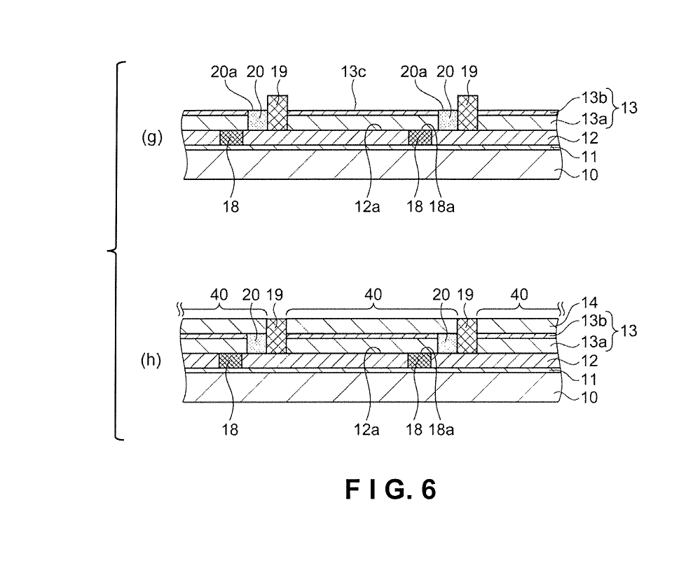

The method for manufacturing the solar cell will next be described. In the present embodiment, a method for manufacturing a CIGS-type solar cell will be described. FIGS. 5 and 6 are process views showing the method for manufacturing a solar cell according to the present embodiment.

In a base layer formation step shown in FIG. 5(a), an insulation layer primarily composed of SiO₂ (silicon dioxide) or an iron fluoride base layer 11 is formed on one surface of a substrate 10 composed of blue sheet glass, stainless steel, or other material. The base layer 11 can be formed by heat treatment or another method. The base layer formation step may be omitted when the substrate 10 as such has the effects of the base layer described above.

In a first partition portion formation step shown in FIG. 5(b), the first partition portions 18 having insulation properties are formed on the base layer 11 to partition the region in which the first electrode layer 12 is formed. The first partition portions 18 are formed, for example, by applying a liquid material that includes an insulating material for forming the first partition portions 18 on the base layer 11 by a printing method, an inkjet method, or another method, and baking the applied solution. The first partition portions 18 are formed in the first partition portion formation step so as to have the same thickness as the first electrode layer 12 formed in the subsequent step.

In a first electrode layer formation step shown in FIG. 5(c), the first electrode layer 12 is formed in the region partitioned by the first partition portions 18. The first electrode layer 12 is formed, for example, by using a printing method, an inkjet method, or another method to apply a liquid material that includes molybdenum (Mo) for forming the first electrode layer 12 in the region partitioned by the first partition portions 18, and baking the applied molybdenum. The first electrode layer 12 is formed so that the top surface 12a of the first electrode layer 12 and the top surfaces 18a of the first partition portions 18 have the same height. Specifically, a uniform, flat surface is formed by the top surface 12a of the first electrode layer 12 and the top surfaces 18a of the first partition portions 18.

In a second partition portion formation step shown in FIG. 5(d), the second partition portions 19 having insulation properties are formed to partition the region on the first electrode layer 12 in which the semiconductor layer 13 and the second electrode layer 14 are formed. The second partition portions 19 are formed, for example, by applying a liquid material that includes an insulating material for forming the second partition portions 19 on the first electrode layer 12 by a printing method, an inkjet method, or another method, and baking the applied insulating material.

In a conductive layer formation step shown in FIG. 5(e), the conductive layer 20 is formed on the first electrode layer 12. In the present embodiment, the conductive layers 20 are formed so as to be adjacent to the second partition portions 19. A material having lower electrical resistivity than the first electrode layer 12 and the second electrode layer 14 is used to form the conductive layers 20. Specifically, copper (Cu) or a material composed primarily of copper, or gold (Au), silver (Ag), nickel (Ni), a copper-manganese compound, or another material may be used to form the conductive layers 20. The conductive layers 20 are formed, for example, by using a printing method, an inkjet method, or another method to apply a liquid material that includes copper for forming the conductive layers 20 on the first electrode layer 12, and baking the applied copper. The conductive layers 20 are formed in the conductive layer formation step so as to have the same thickness as the semiconductor layer 13 formed in the subsequent step.

In a first semiconductor layer formation step shown in FIG. 5(f), the first semiconductor layer 13a is formed on the first electrode layer 12 in the region partitioned by the second partition portions 19. The first semiconductor layer 13a is formed, for example, by using a printing method, an inkjet method, or another method to apply a liquid material that includes a compound semiconductor material composed of copper (Cu), indium (In), gallium (Ga), and selenium (Se) for forming the first semiconductor layer 13a in the region partitioned by the second partition portions 19, and baking the applied compound semiconductor material. A p-type semiconductor layer (CIGS layer) is thereby formed.

In a second semiconductor layer formation step shown in FIG. 6(g), the second semiconductor layer 13b is formed on the first semiconductor layer 13a in the region partitioned by the second partition portions 19. The second semiconductor layer 13b is formed, for example, by using a printing method, an inkjet method, or another method to apply a liquid material that includes a CdS, ZnO, or InS material as the second semiconductor layer 13b in the region partitioned by the second partition portions 19, and baking the applied material. An n-type semiconductor layer is thereby formed. The semiconductor layer 13 is composed of a first semiconductor layer 13a and a second semiconductor layer 13b. The semiconductor layer 13 is formed so that the top surface 13c (top surface of the second semiconductor layer 13b) of the semiconductor layer 13 has the same height as the top surfaces 20a of the conductive layers 20. Specifically, the semiconductor layer 13 is formed so that the top surface 13c of the semiconductor layer 13 and the top surfaces 20a of the conductive layers 20 form a uniform, flat surface.

In a second electrode layer formation step shown in FIG. 6(h), the second electrode layer 14 is formed on the semiconductor layer 13 and on the conductive layers 20, in the region partitioned by the second partition portions 19. The second electrode layer 14 is formed, for example, by using a printing method, an inkjet method, or another method to apply a liquid material that includes ZnOAl or another transparent electrode (TCO) material for forming the second electrode layer 14 in the region partitioned by the second partition portions 19, and baking the applied material. By forming the second electrode layer 14, the first electrode layer 12 and the second electrode layer 14 are electrically connected via the conductive layers 20.

By the process described above, a CIGS-type solar cell 1a can be manufactured in which a plurality of unit cells 40 is connected in series.

Consequently, the effects described below are obtained through the second embodiment in addition to the effects of the first embodiment.

(1) The first partition portions 18 are formed, and the first electrode layer 12 is divided for each unit cell 40. The second partition portions 19 are formed, and the semiconductor layer 13 and the second electrode layer 14 are divided. Furthermore, the conductive layers 20 are formed in advance on the first electrode layer 12, and the first electrode layer 12 and the second electrode layer 14 are electrically connected. Consequently, there is no need to divide (scribe) each of the unit cells 40 using laser light irradiation, a metal needle, or the like in the present embodiment. Furthermore, there is no need to form groove portions for connecting the first electrode layer 12 and the second electrode layer 14 using laser light irradiation, a metal needle, or another method. There is therefore no residue generated by a scribing process or the like, and a highly reliable solar cell can be provided. Since there is also no need to set a scribing width or the like to allow for error in the scribing process, a larger electrical generation region can be formed, and conversion efficiency can be enhanced.

(2) The conductive layers 20 are formed in the regions adjacent to the second partition portions 19. Specifically, the conductive layers 20 are formed in the outermost peripheral portions of the unit cells 40, and the first electrode layer 12 and the second electrode layer 14 are electrically connected. The region in which the first electrode layer 12, the semiconductor layer 13, and the second electrode layer 14 overlap is thereby increased in size, and the efficiency of electrical generation can be further enhanced.

(3) A material having lower electrical resistivity than the first electrode layer 12 and the second electrode layer 14 is used to form the conductive layers 20. The electrical resistance between the first electrode layer 12 and the second electrode layer 14 can thereby be reduced, and conversion efficiency can be increased.

The present invention is not limited to the embodiments described above, and may include such modifications as those described below.

### Modification 1

In the embodiment described above, a description is provided of the structure and other aspects of a CIGS-type solar cell 1, 1a for receiving light from the side of the second electrode layer 14, but the solar cell 1, 1a may also be a CIGS-type solar cell 1 that is capable of receiving light from the side of the substrate 10 as well as from the side of the second electrode layer 14. In this case, a transparent substrate is used as the substrate 10. For example, a glass substrate, a PET substrate, an organic transparent substrate, or the like may be used. Using a transparent substrate enables light to be received from the surface of the substrate 10. The first electrode layer 12 is a transparent electrode layer, and is a ZnOAl or other transparent electrode (TCO: transparent conducting oxides) layer, for example. By forming a transparent electrode layer, light that is incident from the side of the substrate 10 can be made to pass through to reach the semiconductor layer 13. The same effects as those described above can be obtained through this configuration as well.

### GENERAL INTERPRETATION OF TERMS

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Also, the terms “part,” “section,” “portion,” “member” or “element” when used in the singular can have the dual meaning of a single part or a plurality of parts. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

What is claimed is:

1. A solar cell comprising:
a plurality of unit cells connected in series with each of the unit cells including a substrate, a first electrode layer formed on the substrate, a semiconductor layer formed on the first electrode layer, and a second electrode layer formed on the semiconductor layer; and
a first partition portion having insulation properties and partitioning the first electrode layers of the unit cells on the substrate with each the first electrode layers being disposed respectively in a region partitioned by the first partition portion.

2. The solar cell according to claim 1, wherein
a top surface of the first partition portion is substantially flash with top surfaces of the first electrode layers.

3. A solar cell comprising:
a plurality of unit cells connected in series with each of the unit cells including a substrate, a first electrode layer formed on the substrate, a semiconductor layer formed on the first electrode layer, and a second electrode layer formed on the semiconductor layer; and
a second partition portion having insulation properties and partitioning the semiconductor layers and the second electrode layers of the unit cells on the substrate, with each set of the semiconductor layers and the second electrode layers being disposed respectively in a region partitioned by the second partition portion.

4. The solar cell according to claim 3, wherein
the semiconductor layers form a groove portion communicating the first electrode layer with the second electrode layer in a region adjacent to the second partition portion with the second electrode layer being formed in the groove portion.

5. The solar cell according to claim 3, further comprising
a conductive layer disposed in a region adjacent to the second partition portion with the conductive layer electrically connecting the first electrode layer and the second electrode layer.

6. The solar cell according to claim 5, wherein
the conductive layer is formed using a material having lower electrical resistivity than the first electrode layer and the second electrode layer.

7. A method for manufacturing a solar cell having a plurality of unit cells connected in series, each of the unit cells including a substrate, a first electrode layer, a semiconductor layer, and a second electrode layer, the method for manufacturing a solar cell comprising:
forming a first partition portion on the substrate to partition a plurality of regions respectively corresponding to the first electrode layers of the unit cells;
forming the first electrode layer of each of the unit cells in a corresponding one of the regions partitioned by the first partition portion;
forming a second partition portion on the first electrode layer to partition a plurality of regions respectively corresponding to the semiconductor layers and the second electrode layers of the unit cells;
forming the semiconductor layer of each of the unit cells in a corresponding one of the regions partitioned by the second partition portion;
removing a portion of the semiconductor layer of each of the unit cells in the thickness direction to form a groove portion extending to the first electrode layer; and
forming the second electrode layer of each of the unit cells on the semiconductor layer and in the groove portion in a corresponding one of the regions partitioned by the second partition portion.

8. The method for manufacturing a solar cell according to claim 7, wherein
the removing of the portion of the semiconductor layer includes removing the portion of the semiconductor layer in a region adjacent to the second partition portion to form the groove portion in the region adjacent to the second partition portion.

9. A method for manufacturing a solar cell having a plurality of unit cells connected in series, each of the unit cells including a substrate, a first electrode layer, a semiconductor layer, and a second electrode layer, the method for manufacturing a solar cell comprising:
forming a first partition portion on the substrate to partition a plurality of regions respectively corresponding to the first electrode layers of the unit cells;
forming the first electrode layer of each of the unit cells on the substrate in a corresponding one of the regions partitioned by the first partition portion;
forming a second partition portion on the first electrode layer to partition a plurality of regions respectively corresponding to the semiconductor layers and the second electrode layers of the unit cells;
forming a conductive layer on the first electrode layer of each of the unit cells in a corresponding one of the regions partitioned by the second partition portion with the conductive layer electrically connecting the first electrode layer and the second electrode layer;
forming the semiconductor layer of each of the unit cells on the first electrode layer in a corresponding one of the regions partitioned by the second partition portion; and
forming the second electrode layer of each of the unit cells on the semiconductor layer in a corresponding one of the regions partitioned by the second partition portion.

10. The method for manufacturing a solar cell according to claim 9, wherein
the forming of the conductive layer includes forming the conductive layer in a region adjacent to the second partition portion.
